(19) United States
(12) Patent Application Publication
(10) Pub. No.: US 2007/0289864 A1
(43) Pub. Date: Dec. 20, 2007

(54) Large Area Sputtering Target

(76) Inventors: ZHIFEI YE, Fremont, CA (US); Xiaoguang Ma, Fremont, CA (US); Hanzheng Lin, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/424,467

(22) Filed: Jun. 15, 2006

(51) Int. Cl. C23C 14/32; C23C 14/00

(52) U.S. Cl. 204/192.1; 204/298.12

(57) ABSTRACT

A sputtering target forming method, a sputtering target, and a method of using a sputtering target are herein disclosed. Large area sputtering targets are necessary for producing films on large area substrates. To save on material costs, the large area sputtering target can be formed of multiple target tiles that can be placed adjacent each other on a backing plate. The gaps that are present between the target tiles may to be filled to ensure that the backing plate does not sputter and contaminate the sputtering process. The material filling the gaps may be of the same composition as the sputtering target tiles. Alternatively, the entire sputtering target can be plasma sprayed onto the backing plate to ensure that the sputtering target has a unitary sputtering target body across the entire large area backing plate.

### CROSS-REFERENCE TO RELATED APPLICATIONS

This application is related to U.S. patent application Ser. No. ______ (Attorney Docket No. APPM/11000.02/DISPLAY/APVD/RKK), filed on an even date herewith.

### BACKGROUND OF THE INVENTION

1. Field of the Invention

Embodiments of the present invention generally relate to a sputtering target, a method of forming a sputtering target, and a method of using the sputtering target.

2. Description of the Related Art

Physical vapor deposition (PVD) using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (e.g., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

A magnetron having at least a pair of opposed magnetic poles may be disposed near the back of the target to generate a magnetic field close to and parallel to the front face of the target. The induced magnetic field from the pair of opposing magnets trap electrons and extend the electron lifetime before they are lost to an anodic surface or recombine with gas atoms in the plasma. Due to the extended lifetime and the need to maintain charge neutrality in the plasma, additional argon ions are attracted into the region adjacent to the magnetron to form a high-density plasma. Because of the high-density plasma, the sputtering rate is increased.

To deposit thin films over substrates such as wafer substrates, glass substrates, flat panel display substrates, solar panel substrates, and other suitable substrates, sputtering may be used. As substrate sizes increase, so must the target. Therefore, there is a need for a large area sputtering target.

### SUMMARY OF THE INVENTION

The present invention generally comprises a sputtering target forming method, a sputtering target, and a method of using a sputtering target. Large area sputtering targets are necessary for producing films on large area substrates. To save on material costs, the large area sputtering target can be formed of multiple target tiles that can be placed adjacent each other on a backing plate. The gaps that are present between the target tiles may to be filled to ensure that the backing plate does not sputter and contaminate the sputtering process. The material filling the gaps may be of the same composition as the sputtering target tiles. Alternatively, the entire sputtering target can be plasma sprayed onto the backing plate to ensure that the sputtering target has a unitary sputtering target body across the entire large area backing plate.

In one embodiment, a sputtering target is disclosed. The target comprises a plurality of sputtering target tiles on a backing plate. At least one gap between adjacent sputtering target sections may be filled. In another embodiment, the gaps between adjacent tiles are filled to form a target strip. In another embodiment, the target is a unitary, plasma sprayed target. In yet another embodiment, the target is a plurality of wires e-beam profiled to a backing plate.

In another embodiment, a sputtering target forming method is disclosed. The method comprises positioning a plurality of sputtering target tiles on a backing plate, and filling at least one gap between adjacent tiles. The gaps may be filled by plasma spraying or by e-beam profiling a wire into the gap. In another embodiment, the target is formed by plasma spraying the target onto the backing plate. In another embodiment, the target is formed by e-beam profiling a plurality of wires to the backing plate.

In another embodiment, a sputtering method is disclosed. The method comprises biasing the target and depositing sputtered material on a substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of a sputtering apparatus.

FIGS. 2A-2F are cross section views of sputtering target assemblies having gaps between sputtering target tiles according to embodiments of the present invention.

FIG. 2G is a top view of a sputtering target assembly according to one embodiment of the present invention.

FIG. 3A is a cross section view of a sputtering target assembly having a gap according to one embodiment of the present invention.

FIG. 3B is a cross section view of a sputtering target assembly having a gap filled according to one embodiment of the present invention.

FIG. 4A is a cross section view of a sputtering target assembly having a gap according to one embodiment of the present invention.

FIG. 4B is a cross section view of a sputtering target assembly having a gap filled according to one embodiment of the present invention.

FIG. 5A is a cross section view of a backing plate prior to plasma spraying according to one embodiment of the present invention.

FIG. 5B is a cross section view of a sputtering target assembly having a plasma sprayed target surface according to one embodiment of the present invention.

FIG. 5C is a cross section view of a sputtering target assembly having a unitary, planar sputtering target surface according to one embodiment of the present invention.

FIG. 6 is a cross section view of a sputtering target assembly in relation to an e-beam profiling arm according to one embodiment of the present invention.

FIG. 7 is a cross section view of a sputtering target assembly in relation to a plasma spraying arm according to one embodiment of the present invention.

FIG. 8 is a cross section view of a backing plate in relation to a plasma spraying arm according to one embodiment of the present invention.

FIG. 9 is a schematic representation of a target assembly that comprises a plurality of sputtering target tiles.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention comprises a sputtering target forming method, a sputtering target, and a method of using a sputtering target. Large area sputtering targets are necessary for producing films on large area substrates. To save on material costs, the large area sputtering target may be formed of multiple target tiles that may be placed adjacent each other on a backing plate. Gaps that are present between adjacent target tiles may be filled to ensure that the backing plate does not sputter and contaminate the sputtering process. The material filling the gaps may be of the same composition as the sputtering target tiles. Alternatively, the entire sputtering target can be plasma sprayed onto the backing plate to ensure that the sputtering target has a unitary sputtering target body across the entire large area backing plate.

The invention is illustratively described and may be used in a physical vapor deposition system for processing large area substrates, such as a PVD system, available from AKT®, a subsidiary of Applied Materials, Inc., Santa Clara, Calif. However, it should be understood that the sputtering target may have utility in other system configurations, including those systems configured to process large area round substrates. An exemplary system in which the present invention can be practiced is described in U.S. patent application Ser. No. 11/225,922, filed Sep. 13, 2005, which is hereby incorporated by reference in its entirety.

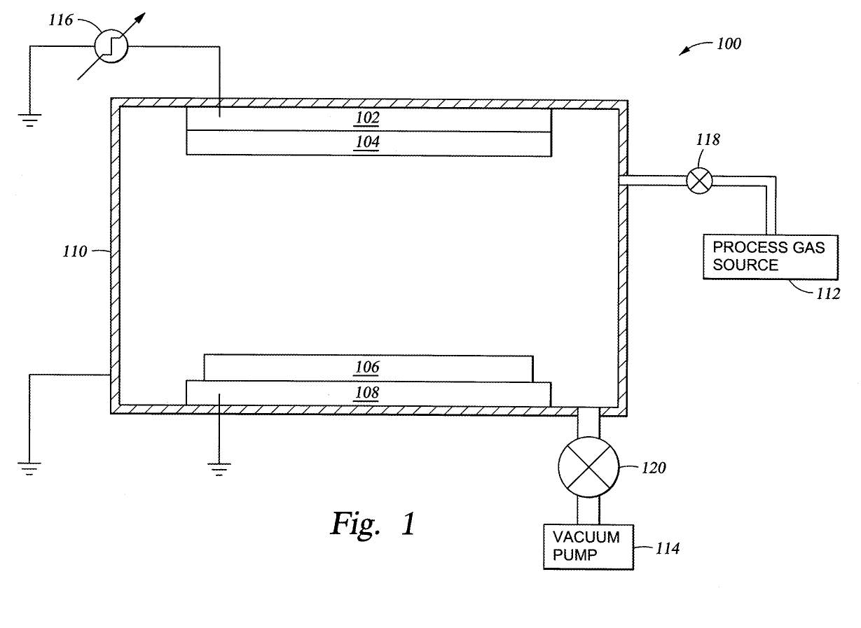

FIG. 1 is a schematic representation of a sputtering apparatus 100. The apparatus comprises a sputtering target 104 coupled to a backing plate 102. The target 104 lies in opposition to a substrate 106 that rests on a susceptor 108. The target 104 may be biased with a power source 116 and both the chamber 110 and the substrate 106 may be grounded. A vacuum pump 114 evacuates the chamber 110 down to an operating pressure. A process gas is provided to the chamber 110 from a process gas source 112 to provide the gaseous environment for sputtering. Both the process gas source 112 and the vacuum pump 114 are sealed from the chamber 110 by valves 118, 120.

As the size of substrates increases, so must the size of the sputtering target. For flat panel displays and solar panels, sputtering targets having a length of greater than 1 meter are not uncommon. Producing a unitary sputtering target of substantial size from an ingot can prove difficult and expensive.

In one embodiment, using a plurality of sputtering target tiles rather than a unitary sputtering target cut from an ingot is an attractive and cheaper alternative. By spacing a plurality of sputtering targets across a single, common backing plate, a large area target may be achieved. The size of the ingot for forming the target tiles may be smaller because the surface area of the target tiles is only a fraction of the surface area of the entire target area. Additionally, it is less expensive to produce an ingot of smaller size than one of larger size. Therefore, producing a plurality of target tiles and spacing them across a backing plate is preferable to forming a single piece target of the same surface area from an ingot from a financial standpoint. In one embodiment, sputtering target strips are used rather than sputtering target tiles. The sputtering target strips may span the length of the backing plate. It is to be understood that the number of target tiles or strips is not limited. Hereinafter, the target tiles and target strips will collectively be referred to as target sections.

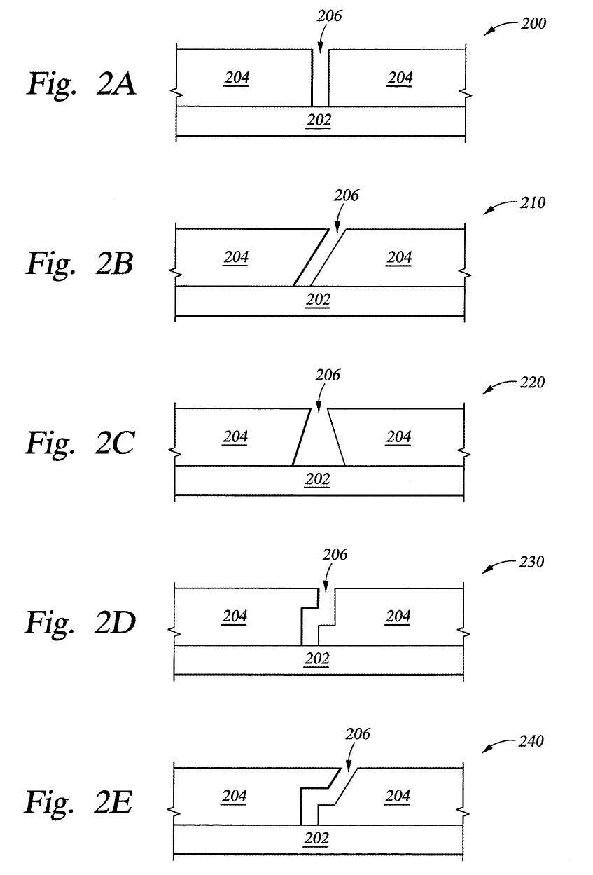

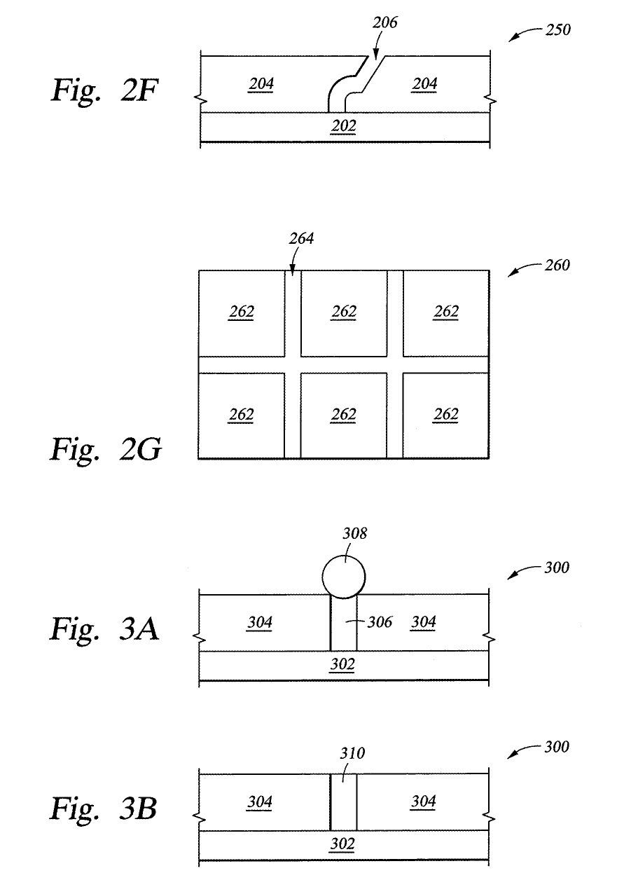

When the sputtering target sections are spaced across a backing plate, a gap may be present between adjacent target sections. The shape of the gap is dependent upon the shape of the edge of the sputtering target sections. For instance, a sputtering target section may be sliced to have a slanted edge, a curved edge, a straight edge, a stepped edge, a stepped shape with curved corners, or a convolute shape to name just a few. FIGS. 2A-2F show several target assemblies 200, 210, 220, 230, 240, 250 in which a gap 206 is present between the target sections 204 that are bonded to the backing plate 202. FIG. 2A shows a straight walled gap. FIG. 2B shows a slanted gap. FIG. 2C shows a dovetail gap. FIG. 2D shows a stepped gap. FIG. 2E shows a stepped gap with curved corners. FIG. 2F shows a convolute gap.

As noted above, a plurality of sputtering target sections may be spaced across the backing plate. FIG. 2G shows a top view of a target assembly 260 in which six target tiles 262 are spaced across a backing plate with gaps 264 therebetween. Gaps between the target tiles 262 may present a problem. If plasma enters the gaps 264, then it is possible for the backing plate to sputter. If the backing plate is not made of exactly the same composition as the sputtering target, then undesired contamination will occur when the backing plate sputters. Furthermore, backing plate sputtering will make it difficult to reuse the backing plate for a refurbished target. Even if the plasma does not immediately reach the backing plate, an oversized interstix (i.e., the intersection point of target tile corners) allows the plasma to sputter the sides of the target tiles 262 facing the interstix. The side sputtering will further enlarge the interstix and increase the likelihood of backing plate sputtering. Filling the gaps 264 with material of the same composition as the sputtering target tiles 262 is beneficial because it will prevent backing plate sputtering. It is to be understood that the invention may be practiced with any tile arrangement such as symmetric, offset, etc.

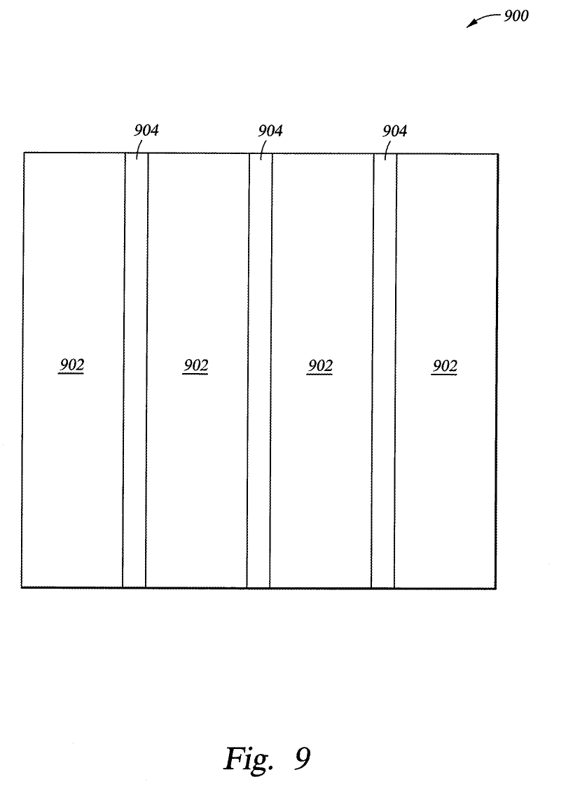

In one embodiment, a plurality of sputtering target tiles are placed together to form a sputtering target strip. The gap between the adjacent tiles may be filled to produce the sputtering target strip. Adjacent sputtering target strips may also have their gaps filled to produce a large area sputtering target. In one embodiment, the sputtering target strips formed from a plurality of sputtering target tiles are placed adjacent each other across a single, common backing plate. FIG. 9 shows one embodiment of a sputtering target assembly 900 that has a plurality of sputtering target strips 902 separated by gaps 904. While four strips 902 have been shown, it is to be understood that more or less target strips 904 may be present. In one embodiment, the gap between adjacent sputtering target strips is filled. In another embodiment, the gap between adjacent sputtering target strips is not filled. In another embodiment, the target strips may be separately powered.

It is to be understood that the present invention may be used to make targets of any size and any dimension. In one embodiment, the sputtering target will have a length greater than 1 meter. In another embodiment, the sputtering target will have a length greater than 2 meters.

In order to fill a gap, the surface of the gap may be prepared to receive the fill material. The surfaces of the gap may be bead blasted to produce a roughened surface. A roughened surface will provide better adhesion for the gap fill material. The backing plate may be bead blasted as well. Care needs to be taken if the bead blasting of the backing plate is to occur before the target sections are bonded to the backing plate. The surface roughness may affect the intimate bonding of the target sections to the backing plate. A mask may be used to ensure that only the gap areas of the backing plate will be bead blasted. It is to be understood that any surface roughening or surface preparation that provides better adhesion for the gap filled material may be used to practice the present invention.

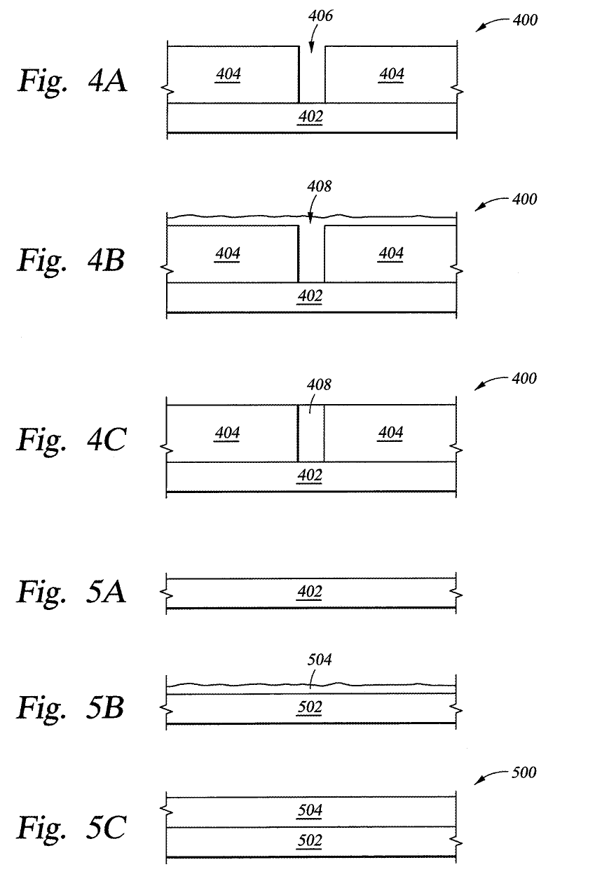

After the surfaces of the gap have been prepared for the gap fill material, the gap filling process may begin. In one embodiment, gap fill material may be electron beam profiled into the gap. FIG. 3A shows a cross section of a target assembly 300 that includes a backing plate 302 with target sections 304 bonded thereto. A gap 306 is present between the adjacent sputtering target sections 304. A wire 308 is placed overlying the gap 306 and within the path of the e-beam. The wire 308 may be of the same composition as the target sections 304 to ensure that the gap fill and the target sections 304 sputter the same material. By sputtering the same material, the gap fill material will not contaminate the sputtering process. The wire 308 has a diameter greater than the gap 306 so that it has sufficient material to fill the gap 306.

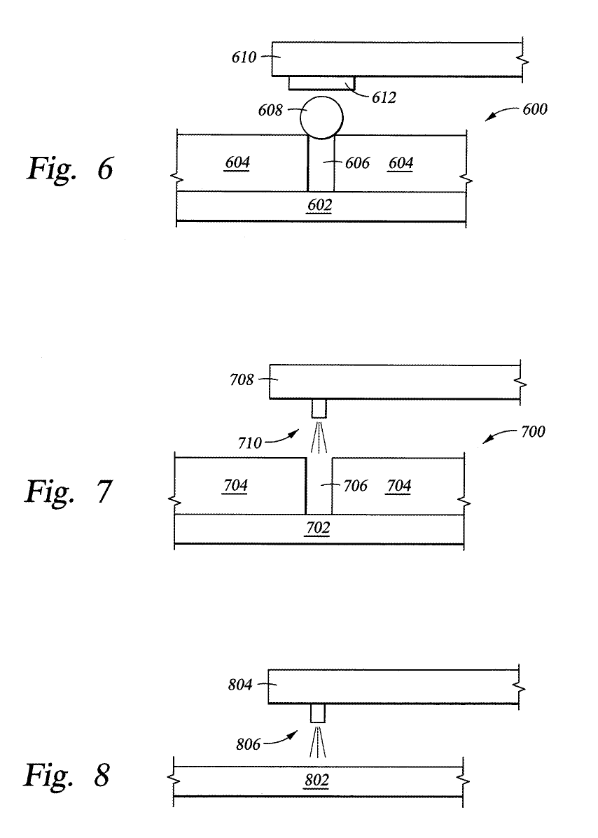

For e-beam profiling, a wire is fed into the path of an e-beam. The wire melts and then drops onto the substrate. The e-beam profiling occurs under vacuum. In one embodiment, the e-beam profiling comprises feeding a wire into the path of the e-beam to melt the wire. The melted wire then drops into the gap between adjacent target tiles to fill the gap. FIG. 6 shows a sputtering target assembly 600 in cross section that has a backing plate 602, target sections 604, gap 606, and wire 608. The wire is e-beam profiled into the gap 606 using an e-beam source 612 provided on an arm 610. After the wire 608 has been e-beam profiled into the gap 606, the wire may form a gap fill material that adheres to the sidewalls of the target sections 604 as well as the backing plate 602.

In another embodiment, the wire 308 may be welded to insert the wire 308 into the gap 306. There are several welding techniques to weld the wire 308 into the gap 306 such as electron beam welding (e-beam), laser welding, or friction stir welding. The welding melts the wire 308 so that it flows into the gap 306 and fills the gap 306. To melt the wire 308 into the gap 306, the welding source will move across all of the wires 308 overlying the gaps 306 in a pattern so that the all of the wire 308 will be welded into the gap 306.

E-beams for welding are normally generated in a relatively high vacuum (lower than 5×10⁻⁵ mbar), but the work piece(s) can be housed in a chamber maintained at a coarser vacuum level, e.g. 5×10⁻³ mbar. It is also possible to project high power e-beams into the atmosphere and produce single pass welds, but the weld width is typically greater than welds made in vacuum. Usually, the electrons are extracted from a hot cathode, accelerated by a high potential, typically 30,000 to 200,000 volts, and magnetically focused into a spot with a power density of the order of 30,000 W/mm². This causes almost instantaneous local melting and vaporization of the work piece material. For example, if the wire is molybdenum, whose melting temperature is 2617° C., the welding location where the e-beam hits should reach a temperature close to or above 2617° C. The e-beam diameter for high vacuum e-beam welding is between about 0.5 mm to about 0.75 mm. The e-beam is thus able to establish a “keyhole” delivering heat, deep into the material being welded. This produces a characteristically narrow, near parallel, fusion zone allowing plane abutting edges to be welded in a single pass. Multiple passes of e-beams can also be applied on the abutting edges to weld work pieces together. An exemplary e-beam tool that may be used to practice the present invention is made by Sciaky of Chicago, Ill. and an exemplary electron welding system that may be used to practice the present invention is made by Stadco of Los Angeles, Calif.

Laser welding is typically conducted in a non-vacuum environment. Laser welding typically directs laser power in excess of 10³ to 10⁵ W/mm² on the surface of the parts to be welded.

Friction stir welding involves joining of metals with a mechanical welding device contacting the work pieces. The welds are created by the combined action of friction heating and mechanical deformation due to a rotating tool. The maximum temperature reached in the joining area is of the order of 0.8 of the melting temperature of the work piece material.

Prior to profiling or welding the wire 308 into the gaps 306 both the wire 308 and the target sections 304 may be preheated. By preheating the wire 306 and target sections 304, the chance of cracking in the profiling or welding seams is reduced. Preheating reduces the amount of thermal expansion mismatch between the fill material and the heat affected zones incurred both during and after the profiling or welding process, which could cause the fill material to crack. The preheating temperature is dependent upon the materials of the target sections 304 and wire 308. For example the sections 304 and wire 308 may be preheated to a temperature that is less than the temperature at which the target sections 304 and wire 308 begin to melt, undergo a change in physical state, or undergo substantial decomposition.

Another method for filling the gaps comprises plasma spraying material into the gaps. FIG. 4A shows a sputtering target assembly 400 that comprises a backing plate 402 with target sections 404 bonded thereto. A gap 406 is present between adjacent target sections 404. Material of the same composition as the target sections 404 may be plasma sprayed into the gaps 406. The resulting structure is shown in cross section in FIG. 4B. The plasma sprayed gap fill material 408 fills the gap 406, but it also deposits on top of the target sections 404. The excess material deposited over the gap 406 and onto the target tiles 404 may be ground back to produce a smoother target surface as shown in FIG. 4C. FIG. 7 shows one embodiment of a sputtering target assembly 700 comprising a backing plate 702, target sections 704, and gap 706 in relation to a plasma spray nozzle 710 on an arm 708. Similar to the profiling and welding, the plasma spray nozzle will move across all of the gaps to be filled in a pattern so that the all of the gaps desired to be filled will be filled.

The excess gap fill material 408 may be removed from the gap 406 and the target surface by grinding the material 408 to remove it. In one embodiment, mechanical polishing removes the excess material 408 from the surface of the sputtering target sections 404 and the gap fill material 408 to produce a uniform, planar target surface as shown in FIG. 4C. It should be understood that the grinding may also be used to remove excess wire material used to fill the gaps as has been described above.

In one embodiment, rather than using a plurality of sputtering target sections, a plurality of wires are placed across a backing plate and then welded (as described above) to the backing plate and to each other. In one embodiment, the wires may be placed across the surface of the backing plate in any orientation. The wires are then welded to the backing plate and to each other. After the wires are welded to the backing plate and to each other, the surface of the target may be planarized using the grinding techniques described above. In another embodiment, the wires may be e-beam profiled onto the backing plate. The entire target may be made by e-beam profiling the wires to the backing plate.

Another alternative to providing adjacent target tiles on a common backing plate is to plasma spray the entire target onto the backing plate. By plasma spraying the target onto the backing plate, the concept of slicing a target to form target tiles from an ingot is not necessary. FIGS. 5A-5C show one embodiment of forming a target assembly 500 by plasma spraying the target material onto a backing plate 502. As can be seen from FIG. 5B, the target material 504 plasma sprayed onto the backing plate 502 is unevenly deposited. Similar to the plasma spray gap filling method discussed above, the excess material 504 may be ground back so that a target with a uniform, planar target is produced as shown in FIG. 5C. The backing plate may be pretreated by bead blasting as discussed above. FIG. 8 shows one embodiment of a backing plate 802 in relation to a plasma spray nozzle 806 on an arm 804. The plasma spray nozzle 806 will move across the entire backing plate 802 so that target material is plasma sprayed across the entire backing plate 802.

Certain target materials present additional challenges. Molybdenum is a very expensive target material to produce. It is difficult to obtain large molybdenum plates (i.e., 1.8 m×2.2 m×10 mm, 2.5 m×2.8 m×10 mm, etc.) and quite expensive. Producing a molybdenum target by conventional hot rolling and hot isostatic pressing (HIP) requires a significant capital investment. A large area (i.e., 1.8 m×2.2 m×10 mm) one piece molybdenum target may cost as much as $15,000,000 to produce. Therefore, for cost considerations alone, it would be beneficial to produce a large area molybdenum target in a more efficient manner such as using multiple tiles with gap fill technology or by plasma spraying the target onto the backing plate. In certain embodiments, e-beam wire profiling and plasma spraying may be used to advantage with molybdenum and other high melting temperature materials because there is less cracking or breaking of the material in comparison to FSW and laser welding.

Producing smaller target sections and spacing them across a single backing plate may create large area sputtering targets. By filling in the gaps between the target sections, the smaller target sections can provide the functionality of a large area sputtering target at a significantly reduced cost. Alternatively, the target may be deposited directly onto the backing plate. Gap fill technology and deposition can ensure the functionality and results of a large area sputtering target is achieved without incurring unreasonable production costs.

While the foregoing is directed to embodiments of the present invention, other and further embodiments of the invention may be devised without departing from the basic scope thereof, and the scope thereof is determined by the claims that follow.

We claim:

1. A sputtering target forming method, comprising:
positioning a plurality of sputtering target tiles on a backing plate, wherein a gap is present between adjacent sputtering target tiles; and
filling at least one of the gaps.

2. The method of claim 1, wherein the filling comprises:
e-beam profiling a wire into the at least one gap.

3. The method of claim 2, further comprising:
preheating the plurality of sputtering target tiles and wire prior to e-beam profiling.

4. The method of claim 1, wherein the target has a length of 1 meter or greater.

5. The method of claim 1, wherein the target has a length of 2 meters or greater.

6. The method of claim 1, wherein the filling comprises plasma spraying material into the gaps.

7. The method of claim 6, further comprising:
removing excess material that has been plasma sprayed onto the target and over the gap so that the plurality of sputtering target tiles and filled gaps have a uniformly planar surface.

8. The method of claim 7, wherein the removing comprises mechanical polishing.

9. The method of claim 6, wherein the sputtering target tiles and the plasma sprayed material each comprise the same composition.

10. The method of claim 9, wherein the composition comprises molybdenum, tungsten, titanium, copper, aluminum, or alloys thereof.

11. The method of claim 6, further comprising:
bead blasting the surfaces of the gap prior to plasma spraying.

12. The method of claim 1, wherein the gap comprises a slanted shape, a dovetail shape, a stepped shape, a stepped shape with curved corners, or a convolute shape.

13. The method of claim 1, wherein the plurality of sputtering target tiles are arranged such that when the gaps between the adjacent sputtering target tiles are filled, at least one sputtering target strip is formed.

14. The method of claim 13, wherein a plurality of sputtering target strips are formed and wherein gaps between adjacent strips are filled.

15. The method of claim 13, wherein a plurality of sputtering target strips are formed and wherein gaps between adjacent strips are not filled.

16. A sputtering target forming method, comprising:
providing a backing plate having a surface;
depositing a sputtering target on the backing plate, wherein the depositing is selected from the group consisting of:
plasma spraying the target onto the backing plate; and
e-beam profiling a plurality of wires across the backing plate.

17. The method of claim 16, wherein the target has a length of 1 meter or more.

18. The method of claim 16, wherein the target has a length of 2 meters or more.

19. The method of claim 16, further comprising:
removing excess sputtering target material that has been plasma sprayed onto the target and so that the sputtering target has a uniformly planar surface.

20. The method of claim 19, wherein the removing comprises mechanical polishing.

21. The method of claim 16, wherein the target comprises molybdenum, tungsten, titanium, copper, aluminum, or alloys thereof.

22. The method of claim 16, further comprising:
bead blasting the surfaces of the backing plate prior to plasma spraying.

23. The method of claim 16, further comprising:
preheating the plurality of wires prior to e-beam profiling.

24. The method of claim 16, further comprising:
removing excess sputtering target material that has been e-beam profiled onto the target and so that the sputtering target has a uniformly planar surface.

25. A method of processing a substrate, comprising:
positioning a substrate opposite a sputtering target;
applying a bias to the sputtering target, wherein the sputtering target comprises a backing plate and a plurality of sputtering target tiles with a gap formed between adjacent sputtering target tiles, wherein the gaps are filled with material; and
depositing material sputtered from the target onto the substrate.

26. The method of claim 25, wherein the target has a length of 1 meter or more.

27. The method of claim 25, wherein the target has a length of 2 meters or more.

28. A method of processing a substrate, comprising:
positioning a substrate opposite a sputtering target;
applying a bias to the sputtering target, wherein the sputtering target comprises a backing plate and a unitary sputtering surface, wherein the unitary sputtering target surface comprises a plasma sprayed target surface or a plurality of wires that have been e-beam profiled to the backing plate; and
depositing the material sputtered from the target onto the substrate.

29. The method of claim 28, wherein the target has a length of 1 meter or more.

30. The method of claim 28, wherein the target has a length of 2 meters or more.
